(19) United States
(12) Patent Application Publication
(10) Pub. No.: US 2026/0239865 A1
(43) Pub. Date: Aug. 13, 2026

(54) MOTHER SUBSTRATE, METHOD OF MANUFACTURING DISPLAY PANEL, AND METHOD OF MANUFACTURING ELECTRONIC DEVICE

(71) Applicant: Samsung Display Co., LTD., Yongin-si (KR)

(72) Inventors: SEUNGWOOK KWON, Yongin-si (KR); HYOYOUNG MUN, Yongin-si (KR); SANGTAE AHN, Yongin-si (KR); HEECHANG YOON, Yongin-si (KR); SEUNG-YEON CHAE, Yongin-si (KR)

(21) Appl. No.: 19/272,120

(22) Filed: Jul. 17, 2025

(30) Foreign Application Priority Data
Feb. 7, 2025 (KR) 10-2025-0016067

(51) Int. Cl. H10K 59/88; H10H 29/01; H10H 29/853; H10K 59/80; H10K 71/80

(52) U.S. Cl. CPC H10K 59/88; H10H 29/0362; H10H 29/853; H10K 59/873; H10K 71/80

(57) ABSTRACT

A mother substrate includes a base substrate, a plurality of cells, a first protective layer, a second protective layer, and a third protective layer. A target region and a first dummy region surrounding the target region are defined on the base substrate. The target region includes active regions and a second dummy region surrounding the active regions. The first protective layer is disposed on one of the plurality of cells and overlaps with an active region of the active regions. The second protective layer is disposed on the base substrate and overlaps with the second dummy region. The third protective layer is disposed on the base substrate, and a central region and an outer region surrounding the central region are defined. The third protective layer has different respective adhesion forces in the outer region and in at least a portion of the central region.

This application claims priority to Korean Patent Application No. 10-2025-0016067, filed on February 7, 2025, and all the benefits accruing therefrom under 35 U.S.C. §119, the content of which is incorporated herein in its entirety by reference.

### BACKGROUND

### Field

The present disclosure relates to a mother substrate having a plurality of protective layers adhered thereon which may prevent infiltration of an etchant during a cell cutting process.

Further, the present disclosure relates to a method of manufacturing a display panel and a method of manufacturing an electronic device, in which the adhesion force of certain regions among the plurality of protective layers is adjusted to facilitate separation of the protective layers from a base substrate after the cell cutting process.

### Description of the Related Art

A display device is typically fabricated by simultaneously forming a plurality of cells on a mother substrate and obtaining individual cells through a cell cutting process. Conventional cell cutting processes apply physical force on the mother substrate bearing the plurality of cells using a wheel, which poses a risk of damaging the cells during processing. To mitigate the risk of damage, a new cell cutting technique has been introduced.

In this new process, a cutting line is pre-formed by irradiating the bottom surface of the mother substrate with a laser. Then, an etchant is sprayed from the top of the mother substrate, allowing the etchant to infiltrate along the cutting line and thereby separate the plurality of cells. During this process, a plurality of protective layers are adhered to the mother substrate to prevent corrosion of the cells by the etchant. The process may include removing the protective layers through a peeling step after the etchant spraying is completed.

However, since the plurality of protective layers are composed of organic materials, their respective curing levels may differ, which can result in residual adhesion in some regions. Consequently, when attempting to peel the protective layers from the mother substrate, incomplete separation may occur, causing the protective layers to stick to the cells, potentially leading to cell breakage.

### SUMMARY

The present disclosure provides a mother substrate having a plurality of protective layers adhered thereon to prevent infiltration of an etchant during a cell cutting process.

More specifically, the present disclosure provides a method of manufacturing a display panel and a method of manufacturing an electronic device, in which adhesion force of certain regions among the plurality of protective layers is adjusted such that the protective layers can be readily separated from the base substrate after the cell cutting process.

An aspect of the present disclosure provides a mother substrate, which may include a base substrate, a plurality of cells, a first protective layer, a second protective layer, and a third protective layer. A target region and a first dummy region surrounding the target region may be defined on the base substrate. The target region may include a plurality of active regions and a second dummy region surrounding the plurality of active regions. Each of the plurality of cells may be disposed on the base substrate and may overlap with a respective active region. The first protective layer may be disposed on at least one of the plurality of cells and may overlap with one of the active regions. The second protective layer may be disposed on the base substrate and may overlap with the second dummy region. The third protective layer may be disposed on the base substrate and defined a central region and an outer region surrounding the central region. The third protective layer may have a first adhesion force in the outer region and may be adhered to the base substrate between the outer region and the first dummy region. The third protective layer may have a second adhesion force smaller than the first adhesion force in at least a portion of the central region.

In an embodiment of the disclosure, the third protective layer may include a base layer and an adhesive layer. The adhesive layer may be disposed below the base layer and may have the first adhesion force in the outer region and the second adhesion force in at least the portion of the central region.

In an embodiment of the disclosure, the third protective layer may include a base layer, an adhesive layer, and a release film layer. The adhesive layer may be disposed below the base layer, and the release film layer may be disposed below the adhesive layer. The release film layer may overlap with the target region and may be non-overlapping with the first dummy region.

In an embodiment of the disclosure, the adhesive layer may have the second adhesion force in a portion of the central region overlapping with the active region and may have the first adhesion force in a portion of the central region overlapping with the second dummy region.

In an embodiment of the disclosure, the adhesive layer may have the second adhesion force in the central region overlapping with both the active region and the second dummy region.

In an embodiment of the disclosure, an opening may be defined in each of the plurality of cells, and a cell cut line overlapping with the second dummy region may be provided on the opposite surface of the base substrate. The base substrate may have a thickness at the cell cut line that is smaller than the thickness of the base substrate where the base substrate overlaps the active region.

In an embodiment of the disclosure, a subset of the plurality of cells arranged along a predetermined direction may be defined as a cell row. The second protective layer may be disposed between the base substrate and the third protective layer, and in a plan view, a portion of the second protective layer may be disposed such that the portion overlaps with the first dummy region in a plan view.

In an embodiment of the disclosure, the second protective layer may extend in the predetermined direction and may shield the opening of each of the plurality of cells included in the cell row.

In an embodiment of the disclosure, the second protective layer may be provided in plurality. The plurality of second protective layers may include a first sub-protective layer and a second sub-protective layer. The first sub-protective layer may surround an edge of a first cell among the plurality of cells included in the cell row. The second sub-protective layer may surround an edge of a second cell adjacent to the first cell in a first direction among the plurality of cells included in the cell row.

In an embodiment of the disclosure, the plurality of second protective layers may further include an auxiliary line and a dummy line. The auxiliary line may connect the first sub-protective layer with the second sub-protective layer, and the dummy line may overlap with the first dummy region.

An aspect of the present disclosure provides a method of manufacturing a display panel. The method of manufacturing a display panel according to an embodiment may include providing a preliminary mother substrate, providing a third protective layer, and attaching the third protective layer. In the step of providing a preliminary mother substrate, the preliminary mother substrate may include a base substrate, a plurality of cells disposed on the base substrate, a first protective layer, and a second protective layer. A target region and a first dummy region surrounding the target region may be defined on the base substrate. The target region may include a plurality of active regions and a second dummy region surrounding the plurality of active regions.

In the step of providing a third protective layer, the third protective layer may have a first adhesion force in an outer region of the third protective layer and a second adhesion force smaller than the first adhesion force in at least a portion of a central region of the third protective layer surrounded by the outer region. In the step of attaching the third protective layer, the third protective layer may be adhered to the base substrate such that the outer region overlaps with the first dummy region and the central region overlaps with the target region.

In an embodiment of the disclosure, the step of providing a third protective layer may include forming a first adhesion force and adjusting a second adhesion force. In the step of forming the first adhesion force, the third protective layer may have the first adhesion force in the outer region. In the step of adjusting the second adhesion force, the second adhesion force may be smaller than the first adhesion force in at least the portion of the central region.

In an embodiment of the disclosure, the step of forming a first adhesion force may include providing a base layer and forming an adhesive layer. In the step of providing a base layer, a base layer may be provided. In the step of forming an adhesive layer, an adhesive layer having the first adhesion force may be formed below the base layer. The step of adjusting a second adhesion force may include emitting UV light, in which the UV light may irradiate a portion of the adhesive layer corresponding to at least the portion of the central region.

In an embodiment of the disclosure, the step of forming a first adhesion force may include providing a base layer and forming an adhesive layer. The step of adjusting a second adhesion force may include placing a release film and laminating the release film. In the step of providing a base layer, a base layer may be provided. In the step of forming an adhesive layer, an adhesive layer having the first adhesion force may be formed below the base layer. In the step of placing a release film, a release film may be disposed below the adhesive layer such that the release film overlaps with the target region and does not overlap with the first dummy region. In the step of laminating the release film, pressure may be applied to the release film to laminate the release film with the adhesive layer.

In an embodiment of the disclosure, the step of providing a preliminary mother substrate may include providing a base substrate, forming a cell, forming a first protective layer, forming a cell cut line, and forming a second protective layer. In the step of providing a base substrate, a base substrate may be provided. In the step of forming a cell, the plurality of cells may be formed on the base substrate, the plurality of cells may respectively overlap the plurality of active regions, and an opening is defined in each of the plurality of cells. In the step of forming a first protective layer, a first protective layer may be formed by coating the plurality of cells with a first organic material. In the step of forming a cell cut line, a cell cut line may be formed between the plurality of cells by irradiating the opposite surface of the base substrate with a laser. In the step of forming a second protective layer, a second protective layer which overlaps with the cell cut line may be formed by coating the base substrate with a second organic material.

In an embodiment of the disclosure, the method may further include spraying an etchant after the step of attaching the third protective layer to the base substrate. In the step of spraying an etchant, an etchant may be sprayed from above the base substrate. During this step, the plurality of cells may be cut along the cell cut line.

The method may further include peeling off the third protective layer, after the step of spraying the etchant. In the step of peeling off the third protective layer, the third protective layer may be detached from the base substrate.

In an embodiment of the disclosure, in the step of forming a second protective layer, the second protective layer may be disposed between the base substrate and the third protective layer. In a plan view, a portion of the second protective layer may overlap with the first dummy region.

In an embodiment of the disclosure, in the step of peeling of the third protective layer, the second protective layer may be detached from the base substrate.

An aspect of the present disclosure provides a method of manufacturing an electronic device. The method of manufacturing an electronic device according to an embodiment of the disclosure may include providing a preliminary mother substrate, providing a third protective layer, attaching the third protective layer, obtaining cells, and connecting a driving unit. In the step of providing a preliminary mother substrate, a preliminary mother substrate may be provided. A base substrate, a plurality of cells disposed on the base substrate, a first protective layer, and a second protective layer overlapping with a cell cut line of the base substrate may be disposed on the preliminary mother substrate. A target region and a first dummy region surrounding the target region may be defined on the base substrate. The target region may include a plurality of active regions and a second dummy region surrounding the plurality of active regions. In the step of providing a third protective layer, the third protective layer may have a first adhesion force in an outer region of the third protective layer and a second adhesion force smaller than the first adhesion force in at least a portion of a central region of the third protective layer surrounded by the outer region. In the step of attaching the third protective layer, the third protective layer may be adhered to the base substrate such that the outer region overlaps with the first dummy region and the central region overlaps with the target region. In the step of obtaining cells, an etchant may be sprayed from above the base substrate, and spraying the etchant may cut and separate the plurality of cells along the cell cut line to obtain a plurality of separated cells. In the step of connecting a driving unit, the separated cells may be connected to a driving unit.

The present disclosure can provide a mother substrate having a plurality of protective layers adhered thereto to prevent infiltration of an etchant during a cell cutting process.

More specifically, the present disclosure can provide a method of manufacturing a display panel and a method of manufacturing an electronic device, in which adhesion force of certain regions among the plurality of protective layers is adjusted such that the protective layers can be readily separated from the base substrate after the cell cutting process.

### BRIEF DESCRIPTION OF THE DRAWINGS

These and/or other features will become apparent and more readily appreciated from the following description of the embodiments, taken in conjunction with the accompanying drawings in which:

FIG. 1 is a perspective view illustrating an electronic device according to an embodiment of the present disclosure;

FIG. 2 is a cross-sectional view illustrating an electronic device according to an embodiment of the present disclosure;

FIG. 3 is a plan view illustrating a display module according to an embodiment of the present disclosure;

FIG. 4 is a cross-sectional view illustrating a display panel according to an embodiment of the present disclosure;

FIG. 5A is a plan view of a mother substrate according to an embodiment of the present disclosure;

FIG. 5B is a cross-sectional view taken along line I-I' of FIG. 5A;

FIG. 5C is a cross-sectional view taken along line II-II' of FIG. 5A;

FIG. 6 is an enlarged view of portion BB illustrated in FIG. 5B;

FIG. 7A is a plan view illustrating a third protective layer according to an embodiment of the present disclosure;

FIG. 7B is a cross-sectional view illustrating the third protective layer according to an embodiment of the present disclosure;;

FIG. 7C is a cross-sectional view illustrating a third protective layer according to another embodiment of the present disclosure;

FIG. 8A is a plan view illustrating a preliminary mother substrate according to another embodiment of the present disclosure;

FIGS. 8B and 8C are plan views illustrating preliminary mother substrates according to yet another embodiment of the present disclosure;

FIG. 9 is a flow diagram illustrating a method of manufacturing a display panel according to an embodiment of the present disclosure;

FIGS. 10A through 10K sequentially illustrate the method of manufacturing a display panel according to an embodiment of the present disclosure;

FIG. 11 is a flow diagram illustrating a method of manufacturing a display panel according to another embodiment of the present disclosure;

FIGS. 12A and 12B sequentially illustrate certain steps in the method of manufacturing a display panel;

FIG. 13 is a block diagram illustrating an electronic device according to an embodiment of the present disclosure; and

FIG. 14 illustrates schematic examples of electronic devices according to various embodiments.

### DETAILED DESCRIPTION

References will now be made in detail to certain embodiments, of which examples are illustrated in the accompanying drawings, where like reference numerals refer to like elements throughout. The embodiments may have a variety of forms and permutations, but the present disclosure shall by no means be construed as being limited to the described embodiments. Rather, the present disclosure shall be construed to encompass all forms, permutations, equivalents and substitutes covered by the technical ideas and scope of the present disclosure. Accordingly, the embodiments are described herein, by referring to the figures, to explain features of the present disclosure.

In the accompanying drawings, the thicknesses, ratios, and dimensions of the illustrated elements may not be to exact scale and may have been exaggerated for the benefit of effective explanation of the technical features associated with these elements. As such, the present disclosure shall not be restricted to the thicknesses, ratios, dimensions, and the like illustrated in the drawings. The term “and/or” encompasses all possible combinations of the associated elements as defined.

An expression such as “comprise” or “include” is intended to specify the presence of a characteristic, a number, a step, an operation, an element, a part, or combinations thereof described in the specification, and shall not be construed to preclude any possibility of presence or addition of one or more other characteristics, numbers, steps, operations, elements, parts, or combinations thereof.

Terms such as, for example, first, second, and the like may be used to describe various components, but the components should not be limited by the terms. The terms as used herein may distinguish one component from other components and are not to be limited by the terms. For example, without departing the scope of the present disclosure, a first component may be referred to as a second component, and similarly, the second component may also be referred to as the first component. The terms of a singular form may include plural forms unless otherwise specified.

The terminology used herein is for the purpose of describing particular embodiments and is not intended to be limiting. As used herein, “a,” “an,” “the,” and “at least one” do not denote a limitation of quantity, and are intended to include both the singular and plural, unless the context clearly indicates otherwise. For example, “an element” has the same meaning as “at least one element," unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, comp

The terms “about” or “approximately” as used herein are inclusive of the stated value and include a suitable range of deviation for the particular value as determined by one of ordinary skill in the art, considering the measurement in question and the error associated with measurement of the particular quantity. The term “about” can mean within one or more standard deviations, or within ± 30%, 20%, 10%, 5% of the stated value, for example.

The term “substantially,” as used herein, means approximately or actually. The term “substantially equal” means approximately or actually equal. The term “substantially the same” means approximately or actually the same. The term “substantially identical” means approximately or actually identical. The term “substantially perpendicular” means approximately or actually perpendicular.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Embodiments are described herein with reference to cross section illustrations that are schematic illustrations of example embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

It should be appreciated that various embodiments of the disclosure and the terms used therein are not intended to limit the technological features set forth herein to particular embodiments and include various changes, equivalents, or replacements for a corresponding embodiment. With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as "A or B”, "at least one of A and B”, "at least one of A or B”, "A, B, or C”, "at least one of A, B, and C”, and "at least one of A, B, or C”, may include any one of, or all possible combinations of the items enumerated together in a corresponding one of the phrases.

It is to be understood that if an element (e.g., a first element) is referred to, with or without the term "operatively" or "communicatively", as "coupled with”, "coupled to”, "connected with”, or "connected to" another element (e.g., a second element), it means that the element may be coupled with the other element directly (e.g., wiredly), wirelessly, or via a third element.

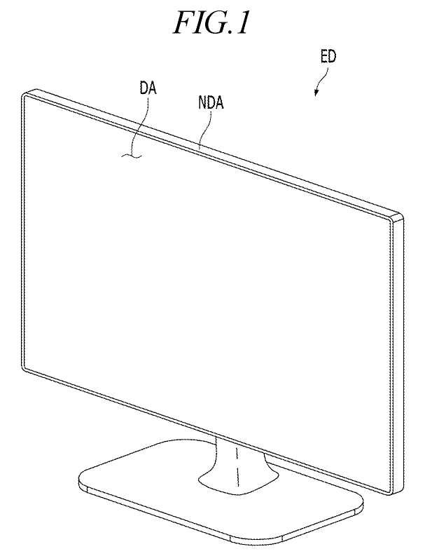

FIG. 1 is a perspective view illustrating an electronic device ED according to an embodiment of the disclosure. In FIG. 1, the electronic device ED is exemplarily illustrated as a display device for reproducing images. The display device may be, but not limited to, a liquid crystal display device (LCD), a field emission display device (FED), an electrophoretic display device (EPD), an electro-wetting display device (EWD), an organic light emitting display device (OLED), or a quantum dot display device (QD), among others.

The electronic device ED may be a device activated in response to electrical signals. For example, the electronic device ED may be a large-sized electronic device such as, for example, a screen or outdoor billboard, or a medium- or small-sized electronic device such as, for example, a desktop computer, laptop computer, navigation system, gaming console, smartphone, or tablet PC. The examples of electronic devices ED described herein are illustrative and may also be employed in other electronic devices without departing from the technical ideas of the disclosure.

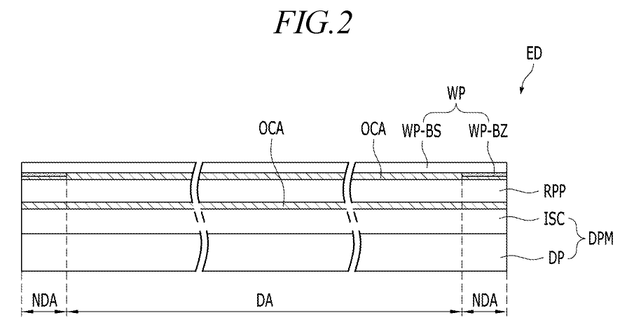

FIG. 2 is a cross-sectional view illustrating an electronic device ED according to an embodiment of the present disclosure. FIG. 2 is simplified to illustrate the lamination relationship of functional panels or functional members constituting the electronic device ED.

As illustrated in FIG. 2, the electronic device ED may include a display panel DP, an input sensing circuit ISC, an anti-reflection member RPP, and a window member WP. The input sensing circuit ISC may be directly disposed on the display panel DP. In the present specification, being "directly disposed" means that no separate adhesive layer or adhesive member is interposed between two components.

Within this specification, the display panel DP and the input sensing circuit ISC disposed thereon may collectively be referred to as a display module DPM. An optically clear adhesive OCA may be disposed between the display module DPM and the anti-reflection member RPP and between the anti-reflection member RPP and the window member WP.

The display panel DP may be configured to generate an image, and the input sensing circuit ISC may be configured to acquire coordinate information of external inputs (e.g., a micro-current or applied pressure). Although not explicitly illustrated, the display module DPM according to an embodiment of the disclosure may further include a protective member disposed on a lower surface of the display panel DP. The protective member and the display panel DP may be bonded together by an adhesive member.

The display panel DP according to an embodiment of the disclosure may be a light-emitting type display panel. For example, the display panel DP may be an organic light-emitting display panel, a quantum dot light-emitting display panel, or a micro light-emitting display panel. The light-emitting layer of the organic light-emitting display panel may include an organic light-emitting material. The inorganic light-emitting display panel may include, based on inorganic materials, the quantum dot light-emitting display panel and the micro light-emitting display panel. Hereinafter, the display panel DP will be described as an organic light-emitting display panel.

The anti-reflection member RPP may be configured to reduce reflectance of external light incident from the upper side of the window member WP. The anti-reflection member RPP according to an embodiment of the disclosure may include a retarder and a polarizer. The anti-reflection member RPP according to another embodiment of the present disclosure may include color filters.

The window member WP according to an embodiment of the disclosure may include a base film WP-BS and a light-blocking pattern WP-BZ. The base film WP-BS may include glass or synthetic resin. The base film WP-BS is not limited to a single layer and may include two or more films bonded by an adhesive member.

The light-blocking pattern WP-BZ may partially overlap the base film WP-BS. The light-blocking pattern WP-BZ may be disposed on the rear surface of the base film WP-BS to define a bezel area, that is, a non-display area NDA, of the electronic device ED.

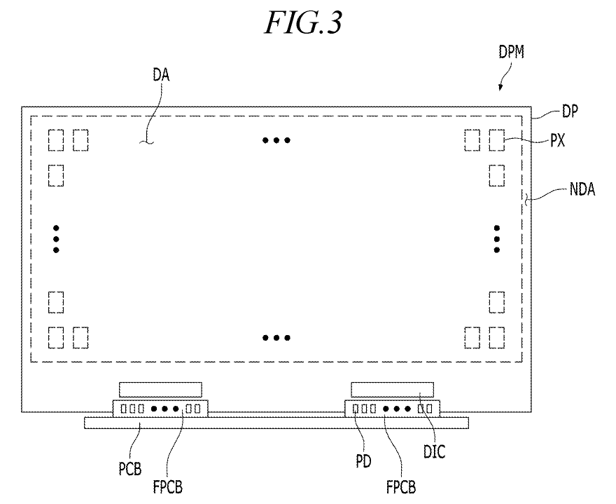

FIG. 3 is a plan view illustrating a display module DPM according to an embodiment of the disclosure. The display module DPM may include a display panel DP, a data driving circuit DIC, a flexible printed circuit board FPCB, and signal pads PD.

A display area DA and a non-display area NDA may be defined on the display panel DP. The non-display area NDA may surround the display area DA. The display area DA may be a region in which an image is displayed. A plurality of pixels PX may be disposed to overlap with the display area DA. The plurality of pixels PX may be disposed in a specific arrangement on the display panel DP. For example, the pixels PX may be arranged in a matrix pattern. Moreover, each of the pixels PX may be configured to display a different color on the display panel DP.

The data driving circuit DIC, the flexible printed circuit board FPCB, and the signal pads PD may be disposed on the non-display area NDA of the display panel DP. The data driving circuit DIC may be mounted on the display panel DP in the form of an integrated circuit (IC) chip. The data driving circuit DIC may be configured to transfer data signals to the pixels PX. The data signals output from the data driving circuit DIC may be transferred to a demultiplexer (not illustrated). The demultiplexer (not illustrated) may be configured to divide and provide the received data signals to the plurality of pixels PX.

The signal pads PD may be mounted on the flexible printed circuit board FPCB. The signal pads PD may be electrically connected to the data driving circuit DIC to transfer signals for operating the data driving circuit DIC.

Moreover, a printed circuit board (not illustrated) may be mounted on the flexible printed circuit board FPCB. However, the disclosure is not limited thereto, and the flexible printed circuit board FPCB and the printed circuit board (not illustrated) may be electrically connected through a separate component.

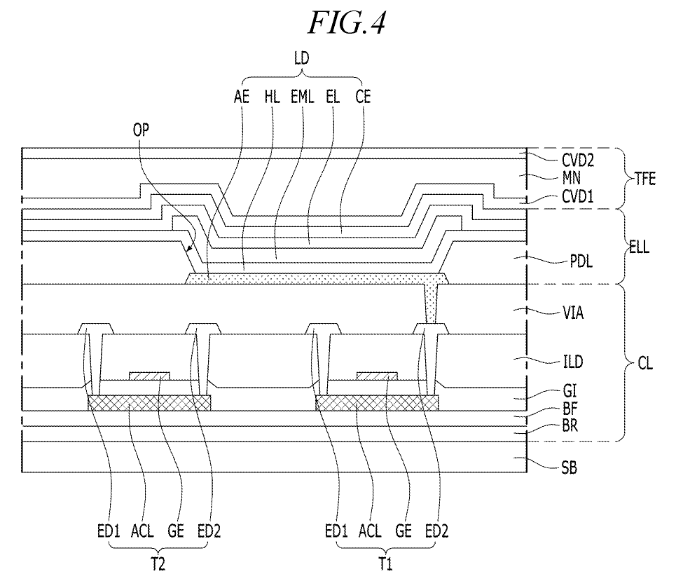

FIG. 4 is a cross-sectional view illustrating the display panel DP according to an embodiment of the present disclosure. While a first transistor T1 and a second transistor T2 are illustrated by way of example in FIG. 4, the structures of the first and second transistors T1, T2 are not limited thereto. Although it is illustrated in FIG. 4 that a second electrode ED2 of the first transistor T1 is in direct contact with an anode electrode AE of the pixel PX, such illustration due to being a cross-sectional representation. In practice, the first transistor T1 may be connected to the anode electrode AE of the pixel PX via an intermediate transistor (not illustrated). However, the configuration is not limited thereto, and in another embodiment of the disclosure, the second electrode ED2 of the first transistor T1 may be in direct contact with the anode electrode AE of the pixel PX.

The display panel DP may include a substrate SB, a circuit layer CL, a light-emitting layer ELL, and an encapsulation layer TFE. The substrate SB may serve as a base for the circuit layer CL. That is, other components of the circuit layer CL may be stacked on the substrate SB. The substrate SB may be formed of an insulating material such as, for example, glass, quartz, or polymer resin. For example, the substrate SB may include polyethersulfone (PES), polyacrylate (PA), polyarylate (PAR), polyetherimide (PEI), polyethylene naphthalate (PEN), polyethylene terephthalate (PET), polyphenylene sulfide (PPS), polyallylate, polycarbonate (PC), cellulosetriacetate (CAT), cellulose acetate propionate (CAP), or a combination thereof.

The substrate SB may also include a metallic material. The substrate SB may be a rigid substrate or a flexible substrate capable of bending, folding, or rolling. An example of a material for the flexible substrate may be, but not limited to, polyimide (PI).

The circuit layer CL may include a barrier layer BR, a buffer layer BF, a gate insulating layer GI, an interlayer insulating layer ILD, a circuit insulating layer VIA, and transistors T1, T2.

The light-emitting layer ELL may be disposed on the circuit layer CL. The light-emitting layer ELL may include a light-emitting diode LD and a pixel defining layer PDL.

The encapsulation layer TFE may seal the light-emitting layer ELL to protect the light-emitting layer ELL from external oxygen or moisture. The encapsulation layer TFE may include a first inorganic layer CVD1, an organic layer MN, and a second inorganic layer CVD2. Although it is depicted in FIG. 4 that the encapsulation layer TFE includes two inorganic layers and one organic layer, the disclosure is not limited thereto. For example, the encapsulation layer TFE may include three inorganic layers and two organic layers, in which case an inorganic layer and an organic layer may be alternately stacked.

Functional layers BR, BF may be disposed on one surface of the substrate SB. These functional layers BR, BF may include the barrier layer BR and the buffer layer BF. The functional layers BR, BF may be configured to prevent impurities present in underlying layers from entering the pixel PX, particularly from diffusing into active regions ACL of the transistors T1, T2 that form the pixel PX, during the manufacturing process.

The active regions ACL that constitute the transistors T1, T2 may be disposed on the buffer layer BF. The active regions ACL may each include poly-silicon or amorphous silicon, and may alternatively include a metal oxide semiconductor.

The active regions ACL may each include a channel region serving as a path through which electrons or holes move, a first ion-doped region and a second ion-doped region disposed on either side of the channel region.

The gate insulating layer GI covering the active regions ACL may be disposed on the buffer layer BF. The gate insulating layer GI may include an organic film and/or an inorganic film. The gate insulating layer GI may include a plurality of inorganic thin films, such as, for example, silicon nitride layers and silicon oxide layers.

Gate electrodes GE constituting the transistors T1, T2 may be disposed on the gate insulating layer GI. At least a portion of scan lines (not illustrated) and light-emission control lines (not illustrated) may be disposed on the gate insulating layer GI.

The interlayer insulating layer ILD covering the gate electrodes GE may be disposed on the gate insulating layer GI. The interlayer insulating layer ILD may include an organic film and/or an inorganic film. The interlayer insulating layer ILD may include a plurality of inorganic or organic thin films, such as, for example, silicon nitride layers and silicon oxide layers.

At least a portion of data lines (not illustrated) and power lines (not illustrated) may be disposed on the interlayer insulating layer ILD. First electrodes ED1 and second electrodes ED2 of the transistors T1, T2 may be disposed on the interlayer insulating layer ILD. The first electrodes ED1 and second electrodes ED2 may be connected with corresponding active regions ACL through contact holes penetrating the gate insulating layer GI and the interlayer insulating layer ILD.

The circuit insulating layer VIA covering the first electrodes ED1 and the second electrodes ED2 may be disposed on the interlayer insulating layer ILD. The circuit insulating layer VIA may include an organic film and/or an inorganic film and may be configured to provide a planar surface. The circuit insulating layer VIA may be disposed between the anode electrode AE and the transistors T1, T2. On the circuit insulating layer VIA, the pixel defining layer PDL and the light-emitting diode LD may be disposed.

The light-emitting diode LD may include an anode electrode AE, a hole control layer HL, a light-emitting diode layer EML, an electron control layer EL, and a cathode electrode CE. The anode electrode AE may be connected to the second electrode ED2 via a contact hole penetrating the circuit insulating layer VIA. An opening OP defined in the pixel defining layer PDL may expose the anode electrode AE.

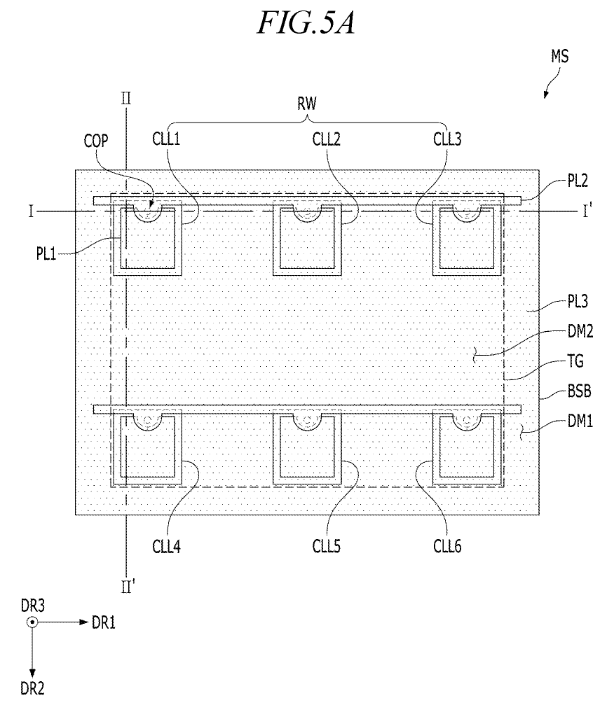

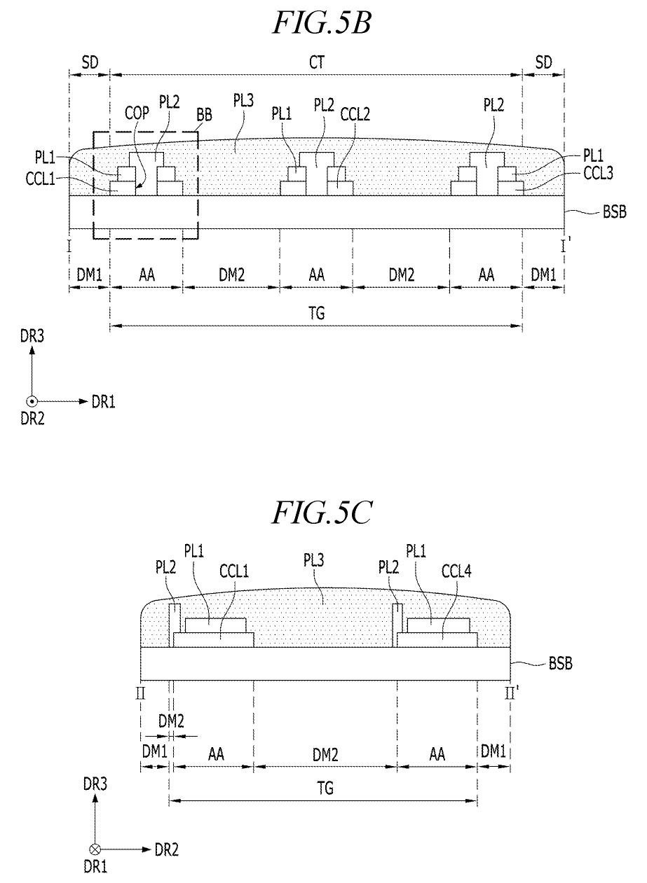

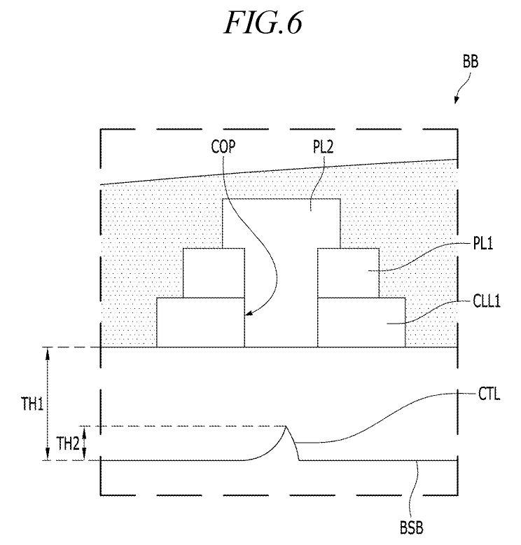

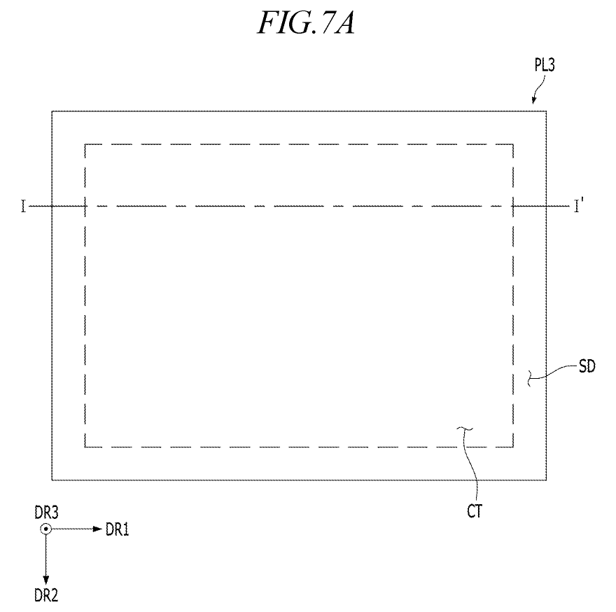

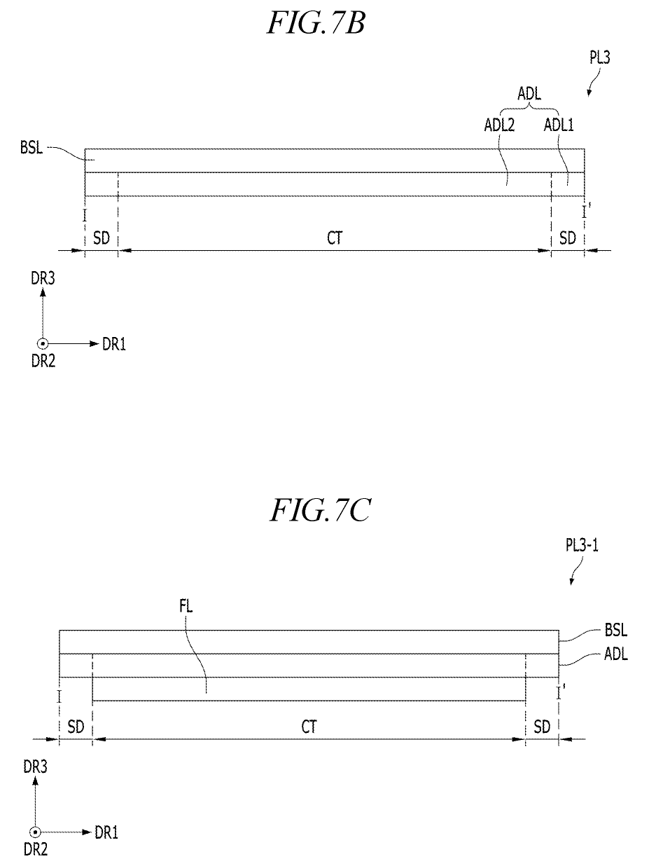

FIG. 5A is a plan view of a mother substrate MS according to an embodiment of the disclosure. FIG. 5B is a cross-sectional view taken along line I-I' of FIG. 5A. FIG. 5C is a cross-sectional view taken along line II-II' of FIG. 5A. FIG. 6 is an enlarged view of portion BB illustrated in FIG. 5B. FIG. 7A is a plan view illustrating a third protective layer PL3 according to an embodiment of the disclosure. FIG. 7B is a cross-sectional view illustrating the third protective layer PL3 according to an embodiment of the disclosure. FIG. 7C is a cross-sectional view illustrating a third protective layer PL3-1 according to another embodiment of the disclosure.

The mother substrate MS according to an embodiment of the disclosure may include a base substrate BSB, a plurality of cells CLL1 - CLL6, a first protective layer PL1, a second protective layer PL2, and a third protective layer PL3.

The base substrate BSB may have a plate shape extending in a first direction D1 and a second direction D2. For example, the base substrate BSB may be in the form of a rectangular plate. The base substrate BSB is a mother substrate of a size on which the plurality of cells CLL1 - CLL6 can be formed.

The base substrate BSB may serve as a base for forming the plurality of cells CLL1 - CLL6. In the present specification, the base substrate BSB is exemplarily described as being formed of glass. Since glass has greater rigidity than plastic materials, it may facilitate the formation of the cells CLL1 - CLL6 without using a separate support substrate. Therefore, using glass for the base substrate BSB may allow omission of processes related to attaching and detaching a support substrate. However, embodiments of the present disclosure are not limited thereto, and the base substrate BSB may be formed of a plastic material having flexibility. For example, the base substrate BSB may be formed of polyimide.

In an embodiment of the disclosure, a target region TG and a first dummy region DM1 surrounding the target region TG may be defined on the base substrate BSB. The target region TG may include a plurality of active regions AA and a second dummy region DM2 surrounding the plurality of active regions AA. Here, the target region TG may be a central region of the base substrate BSB. The plurality of active regions AA may be regions overlapping the plurality of cells CLL1 - CLL6. The first dummy region DM1 may be a side region of the base substrate BSB.

The plurality of cells CLL1 - CLL6 may be disposed on the base substrate BSB. Each of the cells CLL1 - CLL6 may correspond to the display panel DP described earlier in reference to FIG. 3. Each of the cells CLL1 - CLL6 may have a cell opening COP defined therein.

In an embodiment of the disclosure, a subset of the plurality of cells CLL1 - CLL6 arranged along a predetermined direction may be defined as a cell row RW. The predetermined direction may correspond to the first direction DR1.

First to third cells CLL1 - CLL3 may be sequentially arranged along the predetermined direction to form the cell row RW. A fourth cell CLL4 may be disposed adjacent to a first cell CLL1 in the second direction DR2. A fifth cell CLL5 may be disposed adjacent to a second cell CLL2 in the second direction DR2. A sixth cell CLL6 may be disposed adjacent to the third cell CLL3 in the second direction DR2. However, the arrangement of the plurality of cells CLL1 - CLL6 is not limited to this illustrated example.

The number of cells CLL1 - CLL6 illustrated in the present specification is exemplarily illustrated as six. However, the number of cells CLL1 - CLL6 is not limited thereto. The plurality of cells CLL1 - CLL6 may be disposed such that the plurality of cells CLL1 - CLL6 overlap, respectively, with the plurality of active regions AA. The plurality of active regions AA may correspond to regions where the light-emitting diode LD (see FIG. 4) and the encapsulation layer TFE (see FIG. 4) are located. Each of the plurality of cell CLL1 - CLL6 may be electrically connected to an external terminal (not illustrated) through the signal pads PD (see FIG. 3).

In the process of manufacturing the display panel DP, the base substrate BSB may be cut along the edge of each of the plurality of cells CLL1 - CLL6. Accordingly, the edges of the cells CLL1 - CLL6 may be cut and separated to correspond to respective display panels DP.

One of the methods for obtaining the separated cells CLL1 - CLL6 may include a scribing process using a wheel cutter. However, in the present specification, the description is based on a process in which the base substrate BSB is thinned by an etchant to separate the plurality of cells CLL1 - CLL6.

Hereinafter, the roles and arrangement of the first protective layer PL1, the second protective layer PL2, and the third protective layer PL3 will be described. The first, second, and third protective layers PL1, PL2, PL3 may be sequentially adhered to the base substrate BSB to prevent corrosion of the cells CLL1 - CLL6 by the etchant. Moreover, the techniques described herein include peeling off and removing the first, second, and third `protective layers PL1, PL2, PL3 from the base substrate BSB after the etchant spraying step. In particular, the third protective layer PL3 may be removed first, and then the second protective layer PL2 may be peeled off. The first protective layer PL1 may be peeled off during a subsequent module process step following the cell cutting process.

In the present specification, the first protective layer PL1 may be provided in plurality. Each of the plurality of first protective layers PL1 may be disposed, respectively, on the plurality of cells CLL1 - CLL6 and may overlap with the plurality of active regions AA.

The first protective layer PL1 may include a first organic material. The first protective layer PL1 may include, but not limited to, at least one of an acrylic resin, an epoxy resin, and a silicone resin. For example, the first protective layer PL1 may include two or more different resins selected from acrylic, epoxy, and silicone resins.

The second protective layer PL2 may be disposed on the base substrate BSB and may overlap with the second dummy region DM2. In an embodiment, the second protective layer PL2 may extend in a predetermined direction and may be configured to shield the openings COP of the plurality of cells CLL1 - CLL3 included in the cell row RW. The second protective layer PL2 may include a second organic material. For example, the second protective layer PL2 may include, but not limited to, at least one of an acrylic resin, an epoxy resin, and a silicone resin. For example, the second protective layer PL2 may include two or more different types of resins selected from acrylic, epoxy, and silicone resins.

The third protective layer PL3 may be disposed on the base substrate BSB. A central region CT and an outer region SD surrounding the central region CT may be defined in the third protective layer PL3. In FIG. 5B, the third protective layer PL3 is depicted as a single layer for the convenience of illustration. This illustration is to depict the adhesion of the third protective layer PL3 to the base substrate BSB. In practice, the third protective layer PL3 may be constituted with multiple layers.

In an embodiment of the disclosure, the third protective layer PL3 may have a first adhesion force in the outer region SD. In an embodiment of the disclosure,, in at least a portion of the central region CT, the third protective layer PL3 may have a second adhesion force smaller than the first adhesion force. Thus, the third protective layer PL3 may be adhered to the base substrate BSB with the first adhesion force between the outer region SD and the first dummy region DM1. That is, as the first, second, and third protective layers PL1, PL2, PL3 protect and shield the plurality of cells CLL1 - CLL6, corrosion caused by the etchant may be prevented. The material and configuration of the third protective layer PL3 will be described in greater detail with reference to FIGS. 7A through 7C.

Referring to FIG. 6, as described herein, a process may be performed in which the thickness of the base substrate BSB is reduced by an etchant, thereby separating the plurality of cells CLL1 - CLL6.

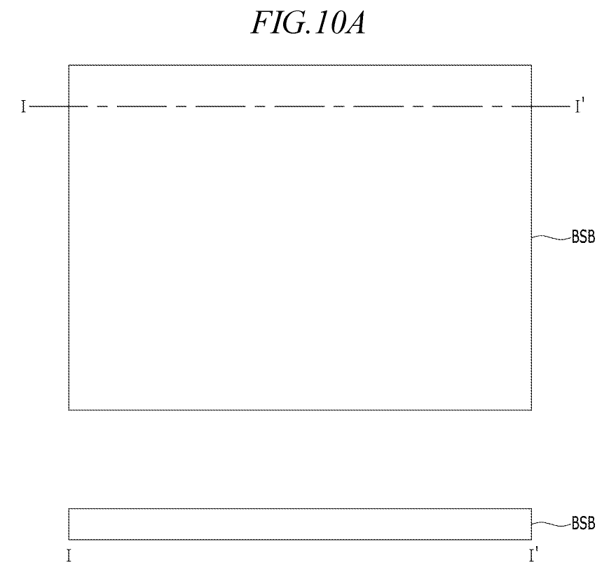

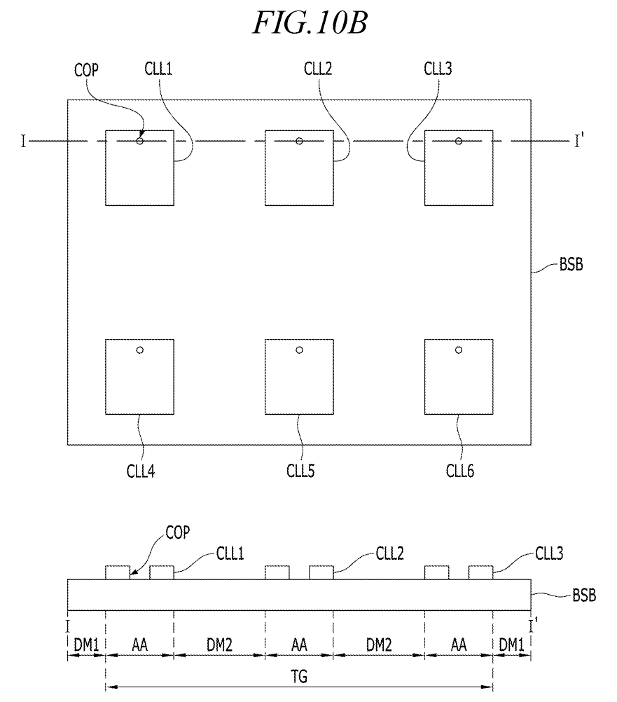

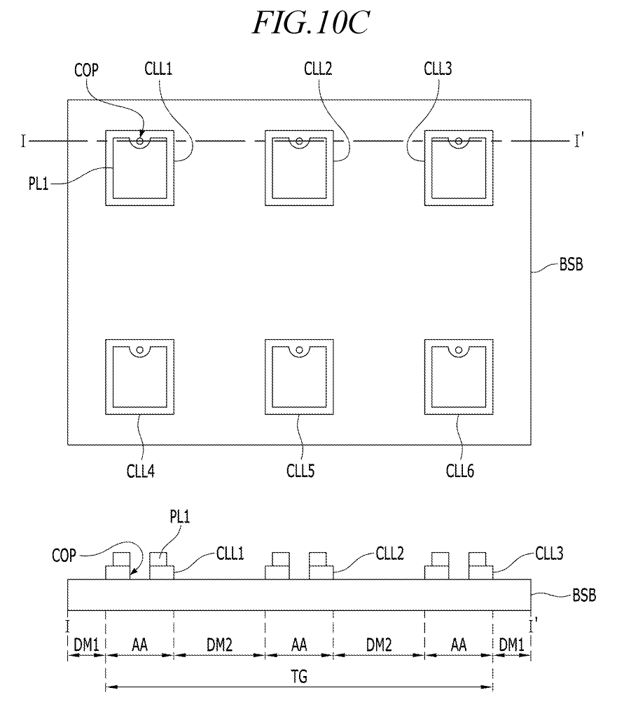

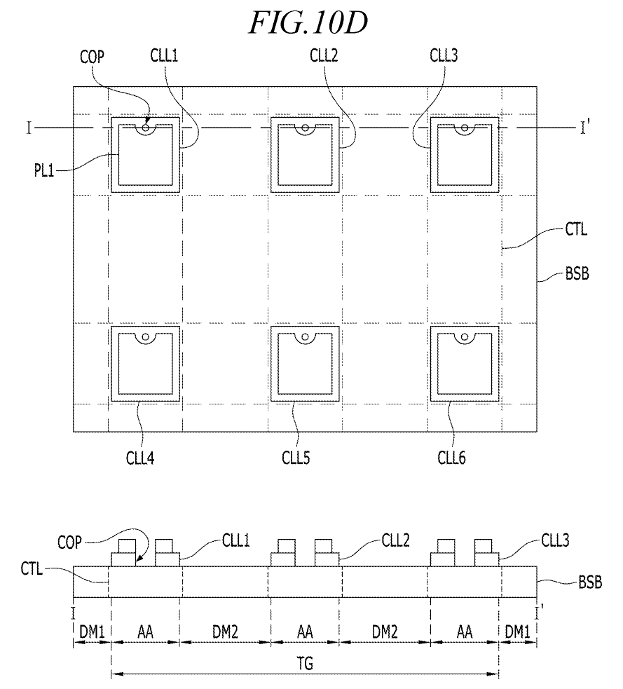

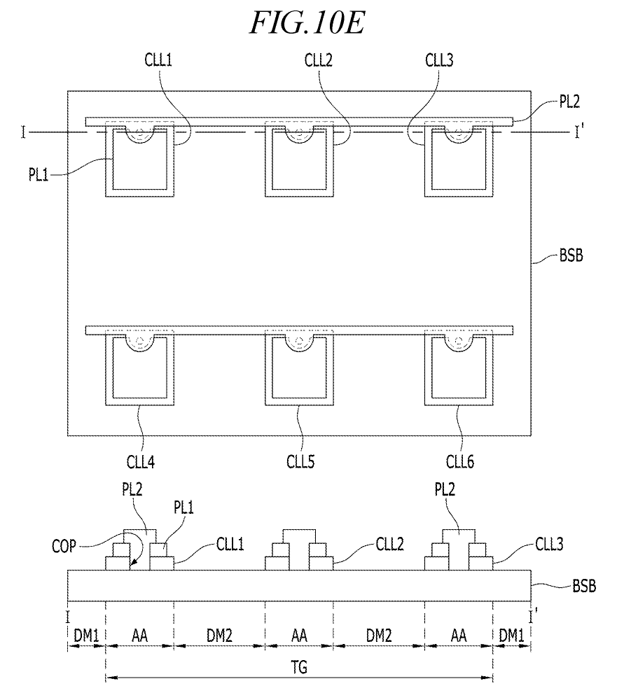

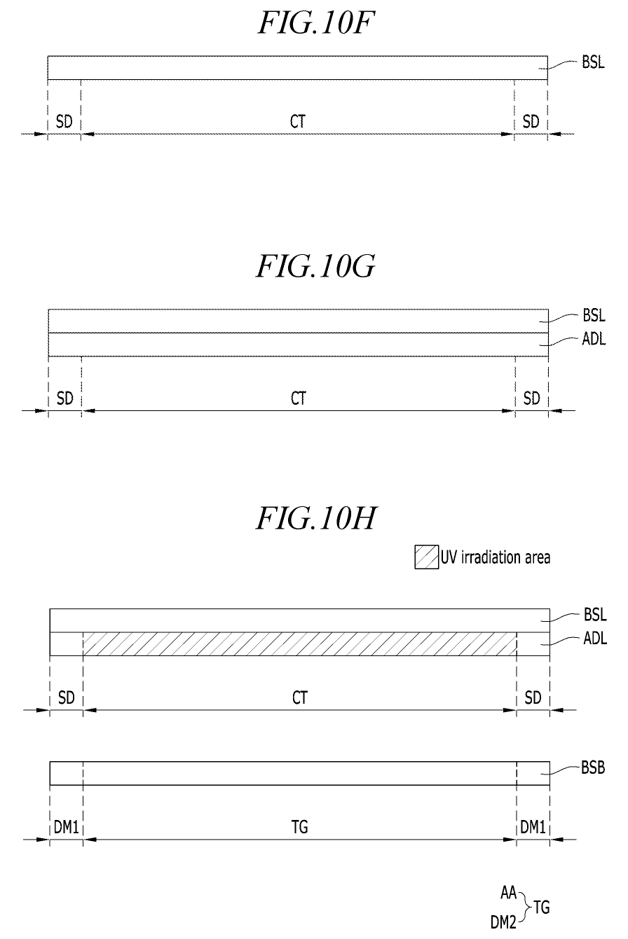

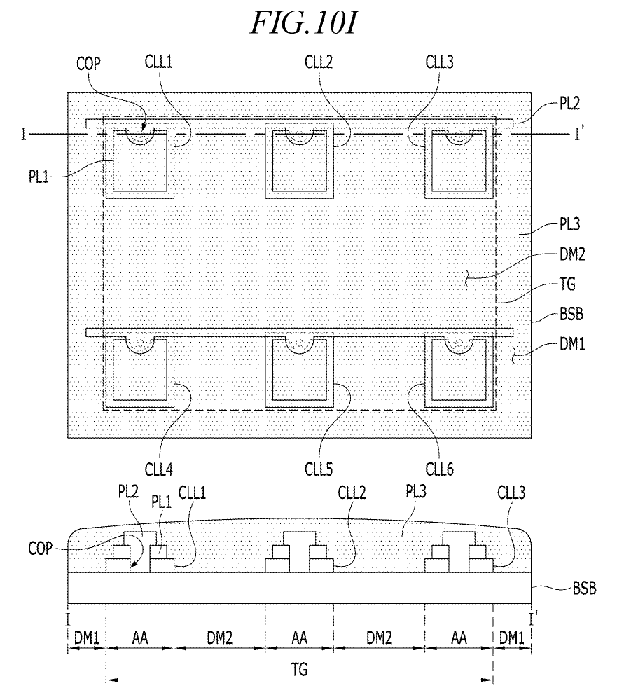

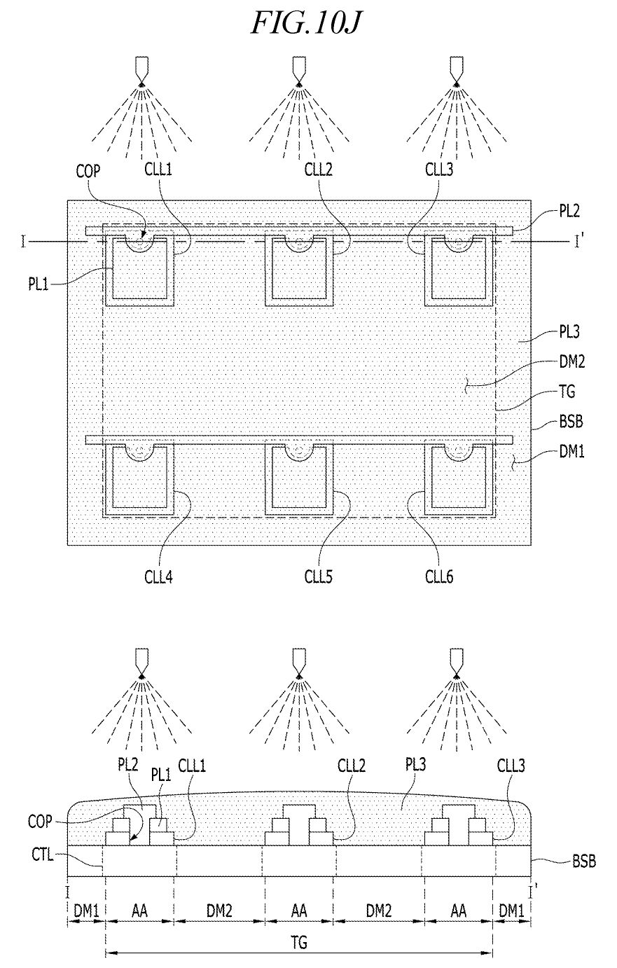

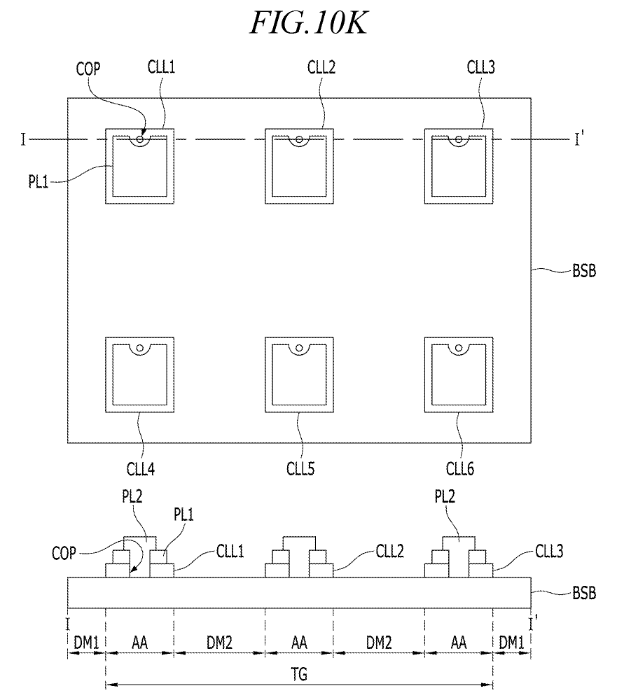

To this end, a cell cut line CTL for cutting the plurality of cells CLL1 - CLL6 may be provided by irradiating the opposite surface of the base substrate BSB with a laser. As will be described later with reference to FIG. 10J, an etchant may infiltrate the cell cut line CTL, etching away the base substrate BSB. As a result, the plurality of cells CLL1 - CLL6 may be cut and separated along the cell cut line CTL. In an embodiment of the disclosure, a second thickness TH2 of the base substrate BSB at the cell cut line CTL may be smaller than a first thickness TH1 of the base substrate BSB in a region overlapping the plurality of active regions AA.

Referring to FIGS. 7A and 7B, the third protective layer PL3 according to an embodiment of the disclosure may include a base layer BSL and adhesive layers ADL1, ADL2. The adhesive layers ADL1, ADL2 may include a first adhesive layer ADL1 and a second adhesive layer ADL2. In an embodiment of the disclosure, the central region CT and an outer region SD surrounding the central region CT may be defined in the third protective layer PL3. The third protective layer PL3 may include an acid-resistant material that does not react with strong acid or hydrofluoric acid. That is, the third protective layer PL3 may be an acid-resistant film.

The base layer BSL may include a plastic film. For example, the base layer BSL may be formed of polyethersulfone (PES), polyacrylate (PAR), polyetherimide (PEI), polyethylene naphthalate (PEN), polyethylene terephthalate (PET), polyphenylene sulfide (PPS), polyallylate, polyimide (PI), polycarbonate (PC), or polyarylene ether sulfone. However, embodiments of the present disclosure are not limited thereto.

The adhesive layers ADL1, ADL2 may be disposed below the base layer BSL. Among the adhesive layers ADL1, ADL2, the first adhesive layer ADL1 may be a layer having a first adhesion force in the outer region SD, and the second adhesive layer ADL2 may be a layer having a second adhesion force smaller than the first adhesion force in the central region CT.

In an embodiment of the disclosure, the first and second adhesive layers ADL1, ADL2 may have an integrated structure. The adhesive layers ADL1, ADL2 may be formed by applying a coating of a liquid adhesive below the base layer BSL or by laminating a pre-formed adhesive layer onto the base layer BSL. The liquid adhesive may include at least one of an organic component, an inorganic component, and an organic-inorganic composite component. For example, the liquid adhesive may include or be a cured product of at least one of a urethane acrylate-based compound, an acryl ester-based compound, an acrylate-based compound, and an epoxy acrylate-based compound.

Methods for applying a coating of the liquid adhesive below the base layer may include the use of a roll coater (not illustrated), a knife coater (not illustrated), or a micro gravure coater (not illustrated). In the micro gravure coating method (not illustrated), the liquid adhesive is placed in a pan (not illustrated), and the base layer BSL is transported by a transport roller (not illustrated) while a coating roller (not illustrated) applies a coating of the liquid adhesive onto the base layer BSL. Although not explicitly illustrated, a drying step (not illustrated) may be further performed for a predetermined period after the coating of the liquid adhesive is applied below the base layer BSL.

Lamination may refer to a process of bonding the base layer BSL and the adhesive layers ADL1, ADL2 to each other using an adhesive. The lamination process should maintain optical properties during the process and should avoid defects such as, for example, bubbles and changes over time. Lamination methods may include atmospheric roll lamination, vacuum face-to-face lamination, atmospheric curved roll lamination, or vacuum pad lamination.

The adhesive layers ADL1, ADL2 may be organic adhesive layers such as, for example, a pressure-sensitive adhesive (PSA) film, an optically clear adhesive (OCA) film, or an optically clear resin (OCR). The organic adhesive layer may include adhesive materials such as, for example, polyurethane, polyacrylate, polyester, epoxy, or polyvinyl acetate.

Moreover, the adhesive layers ADL1, ADL2 may include a UV-curable adhesive. The UV-curable adhesive may normally exhibit adhesion but lose adhesion when exposed to ultraviolet light. The UV-curable adhesive is not particularly limited thereto. The raw materials for the UV-curable adhesive may include acrylate or silicone, and auxiliary agents such as, for example, ester rubber or phenol resin may be used.

In an embodiment of the disclosure, the third protective layer PL3 may have the first adhesion force in the outer region SD. In some aspects, the third protective layer PL3 may have the second adhesion force, which is smaller than the first adhesion force, in at least a portion of the central region CT. Preferably, the second adhesion force may be zero. However, the second adhesion force is not limited thereto and may be a predefined value smaller than the first adhesion force. Due to the difference in adhesion forces across regions of the third protective layer PL3, the third protective layer PL3 may be readily peeled off from the base substrate BSB after the etchant spraying step. Further description regarding this will be provided later with reference to FIG. 10K.

In an embodiment of the disclosure, the second adhesive layer ADL2 may have the second adhesion force between the central region CT and the plurality of the active regions AA.

In an embodiment of the disclosure, the second adhesive layer ADL2 may have the first adhesion force between the central region CT and the second dummy region DM2.

Moreover, in an embodiment of the disclosure, the second adhesive layer ADL2 may have the second adhesion force between the central region CT and the target region TG.

Although not explicitly illustrated, each layer of the third protective layer PL3 may be pressed and bonded by a pressure roller (not illustrated) to have a film shape.

Referring to FIG. 7C, a third protective layer PL3-1 according to an embodiment of the present disclosure may include a base layer BSL, an adhesive layer ADL, and a release film layer FL. Similar to FIGS. 7A and 7B, a central region CT and an outer region SD may be defined in the third protective layer PL3-1. The outer region SD may surround the central region CT. Since the material and arrangement of the base layer BSL and the adhesive layer ADL are substantially the same as those described with reference to FIGS. 7A and 7B, a detailed description thereof will be omitted.

The release film layer FL may be disposed below the adhesive layer ADL.

In an embodiment of the disclosure, the release film layer FL may be disposed such that the release film layer FL overlaps with the target region TG and is non-overlapping with the first dummy region DM1. That is, the release film layer FL may be disposed to partially overlap a portion of the adhesive layer ADL, and the region of the adhesive layer ADL where adhesion force remains may be adhered to the base substrate BSB with the first adhesion force in the first dummy region DM1. The release film layer FL may include, but not limited to, at least one of polyethylene terephthalate (PET), polypropylene (PP), cast polypropylene (CPP), polyurethane (PU), and polyolefin (PO).

In an embodiment of the disclosure, the techniques described herein include removing the first protective layer PL1, the second protective layer PL2, and the third protective layer PL3 after the etchant spraying step. As described herein, the first to third protective layers PL1, PL2, PL3 are sequentially adhered to the base substrate BSB. By differentiating the adhesion force of certain regions of the third protective layer PL3, the third protective layer PL3 may adhere only to the base substrate BSB and may not adhere to the first and second protective layers PL1, PL2. Accordingly, when peeling off the third protective layer PL3 from the base substrate BSB, the third protective layer PL3 may be smoothly detached without adhering to the first and second protective layers PL1, PL2.

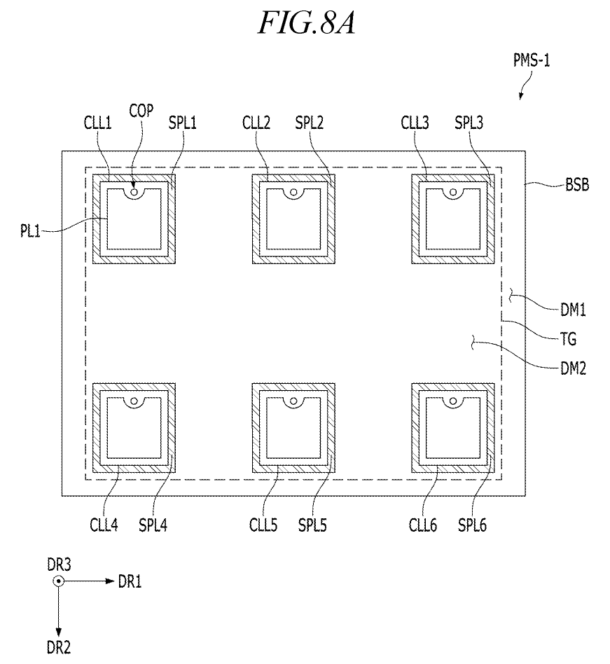

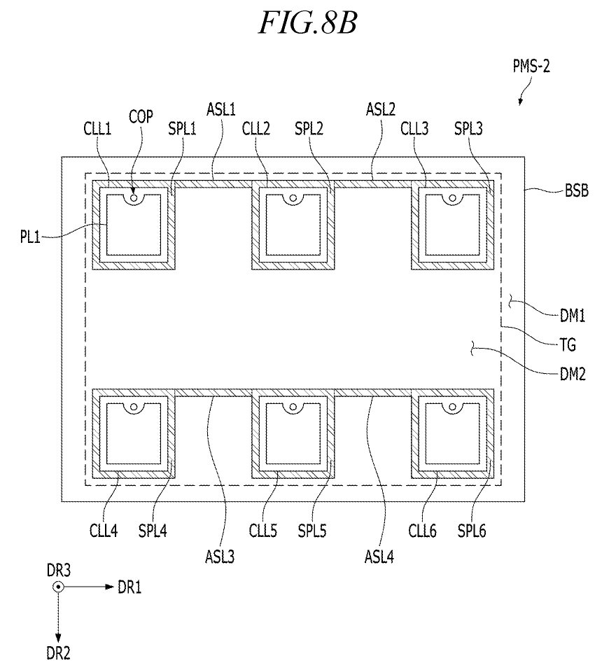

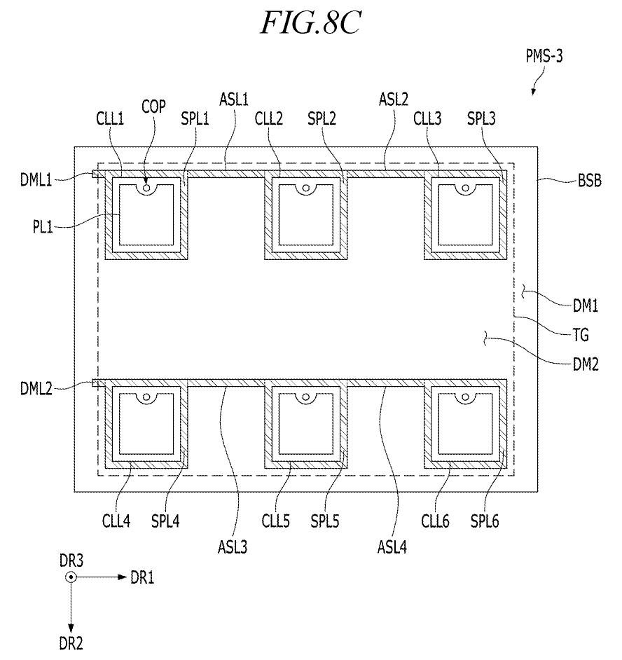

FIG. 8A is a plan view illustrating a preliminary mother substrate PMS-1 according to another embodiment of the present disclosure. Compared to FIG. 5A, it can be seen that the shape of the second protective layer PL2 is different. In FIG. 5A, one end of the second protective layer PL2 is connected to another, forming a bar shape. In contrast, in FIG. 8A, the second protective layer PL2 may surround the edges of the plurality of cells CLL1 - CLL6. In the present specification, the second protective layer PL2 may be provided in plurality. The second protective layer PL2 may include first through sixth sub-protective layers SPL1 - SPL6.

The first sub-protective layer SPL1 may surround the edge of the first cell CLL1. The second sub-protective layer SPL2 may surround the edge of the second cell CLL2. The third sub-protective layer SPL3 may surround the edge of the third cell CLL3. The fourth sub-protective layer SPL4 may surround the edge of the fourth cell CLL4. The fifth sub-protective layer SPL5 may surround the edge of the fifth cell CLL5. The sixth sub-protective layer SPL6 may surround the edge of the sixth cell CLL6.

FIGS. 8B and 8C are plan views illustrating preliminary mother substrates PMS-2, PMS-3 according to yet another embodiment of the present disclosure. Referring to FIG. 8B, the second protective layer PL2 may further include a first auxiliary line ASL1, a second auxiliary line ASL2, a third auxiliary line ASL3, and a fourth auxiliary line ASL4. The first auxiliary line ASL1 may connect the first sub-protective layer SPL1 and the second sub-protective layer SPL2 to each other. The second auxiliary line ASL2 may connect the second sub-protective layer SPL2 and the third sub-protective layer SPL3 to each other. The third auxiliary line ASL3 may connect the fourth sub-protective layer SPL4 and the fifth sub-protective layer SPL5 to each other. The fourth auxiliary line ASL4 may connect the fifth sub-protective layer SPL5 and the sixth sub-protective layer SPL6 to each other.

As such, owing to the second protective layer PL2 further including the auxiliary lines ASL1 - ASL4 and each portion of the second protective layer PL2 being interconnected, this structure may facilitate simultaneous peeling of the second protective layer PL2 when the third protective layer PL3 is peeled from the base substrate BSB after the cell cutting process.

Moreover, referring to FIG. 8C, the second protective layer PL2 may further include dummy lines DML1, DML2 overlapping with the first dummy region DM1. Specifically, the first dummy line DML1 may extend from one side of the first sub-protective layer SPL1 and may be disposed such that the first dummy line DML1 overlaps with the first dummy region DM1. The second dummy line DML2 may extend from one side of the fourth sub-protective layer SPL4 and may be disposed such that the second dummy line DML2 overlaps with the first dummy region DM1.

By disposing the dummy lines DML1, DML2 of the second protective layer PL2 to overlap with the first dummy region DM1, the structure may also facilitate peeling of the second protective layer PL2 together with the third protective layer PL3 from the base substrate BSB after the cell cutting process. Specifically, the dummy lines DML1, DML2 of the second protective layer PL2 may be adhered to the third protective layer PL3 in the first dummy region DM1, and the second protective layer PL2 may also be removed simultaneously when one side of the third protective layer PL3 is pulled in a predetermined direction by a peeling pin (not illustrated).

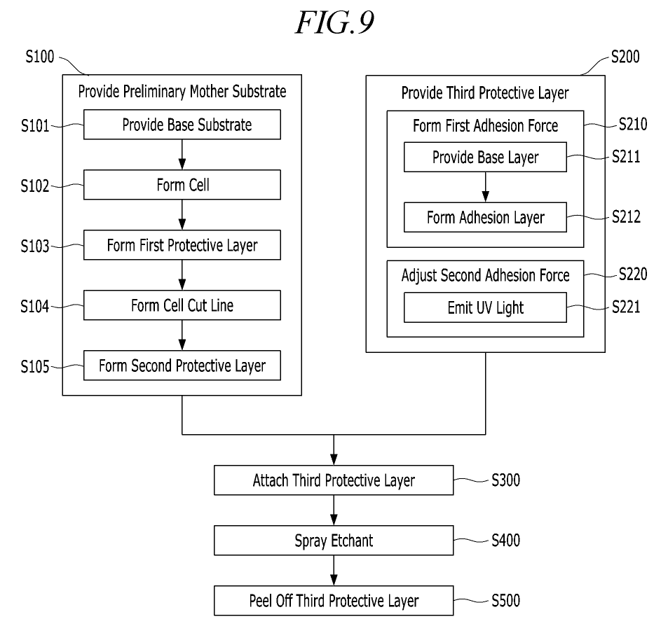

FIG. 9 is a flow diagram illustrating a method of manufacturing a display panel according to an embodiment of the disclosure. FIGS. 10A through 10K sequentially illustrate the method of manufacturing a display panel according to an embodiment of the present disclosure.

In the descriptions of the methods and processes herein, the operations may be performed in a different order than the order shown and/or described, or the operations may be performed in different orders or at different times. Certain operations may also be left out of the flowcharts, one or more operations may be repeated, or other operations may be added. Descriptions that an element “may be disposed,” “may be formed,” “may be provided,” and the like include methods, processes, and techniques for disposing, forming, providing, and the like in accordance with example aspects described herein.

The display panel manufacturing method S10 may include providing a preliminary mother substrate (S100), providing a third protective layer (S200), attaching the third protective layer (S300), spraying an etchant (S400), and peeling off the third protective layer (S500).

The step of providing a preliminary mother substrate (S100) may include providing a base substrate (S101), forming a cell (S102), forming a first protective layer (S103), forming a cell cut line (S104), and forming a second protective layer (S105).

The step of providing the third protective layer (S200) may include forming a first adhesion force (S210) and adjusting a second adhesion force (S220). The step of forming a first adhesion force (S210) may include providing a base layer (S211) and forming an adhesive layer (S212). The step of adjusting a second adhesion force (S220) may include emitting UV light (S221). Emitting the UV light (S221) may include irradiating a portion of the adhesive layer.

For the convenience of description, the present specification first describes the step of providing the preliminary mother substrate (S100), followed by the step of providing the third protective layer (S200). However, the order of these process steps is not limited thereto. For example, the step of providing the preliminary mother substrate (S100) and the step of providing the third protective layer (S200) may be performed in parallel, or the step of providing the third protective layer (S200) may be performed prior to the step of providing the preliminary mother substrate (S100).

FIGS. 10A through 10K sequentially illustrate the method of manufacturing a display panel according to an embodiment of the present disclosure. Particularly, FIGS. 10A through 10E sequentially illustrate the step of providing a preliminary mother substrate (S100) in the display panel manufacturing method S10.

Referring to FIGS. 9 and 10A, the step of providing a base substrate (S101) may be carried out. In the step of providing the base substrate (S101), a base substrate BSB is provided. Hereinafter, the regions defined on the base substrate BSB have been previously described in detail with reference to FIGS. 5A through 6 and thus will not be described repeatedly.

Referring to FIGS. 9 and 10B, after the step of providing a base substrate (S101), the step of forming a cell (S102) may be performed. In the step of forming a cell (S102), a plurality of cells CLL1 - CLL6 may be formed on the base substrate BSB. The plurality of cells CLL1 - CLL6 may be disposed such that the plurality of cells CLL1 - CLL6 respectively overlap with a plurality of the plurality of the active regions AA.

Referring to FIGS. 9 and 10C, after the step of forming a cell (S102), the step of forming a first protective layer (S103) may be performed. In the step of forming a first protective layer (S103), a first protective layer PL1 may be formed by applying a coating of a first organic material onto the plurality of cells CLL. Hereinafter, the material and configuration of the first protective layer PL1 have already been described with reference to FIGS. 5A through 6 and thus will not be redundantly described.

Referring to FIGS. 9 and 10D, after the step of forming a first protective layer (S103), the step of forming a cell cut line (S104) may be performed. The cell cut line CTL may be formed on the opposite surface of the base substrate BSB. Specifically, the cell cut line CTL may be formed by irradiating the rear surface of the base substrate BSB with a laser (not illustrated). The cell cut line CTL may overlap with the edge portions of the plurality of cells CLL1 - CLL6.

Referring to FIGS. 9 and 10E, after the step of forming a cell cut line (S104), the step of forming a second protective layer (S105) may be performed. In the step of forming a second protective layer (S105), a second protective layer PL2 may be formed on the base substrate BSB.

FIGS. 10F through 10H sequentially illustrate the step of providing a third protective layer (S200) in the display panel manufacturing method S10.

Referring to FIGS. 9 and 10F, the step of providing a base layer (S211) may be performed. Since the material of the base layer and the regions defined therein have already been described with reference to FIGS. 7A and 7B, repeated description will be omitted.

Referring to FIGS. 9 and 10G, after the step of providing a base layer (S211), the step of forming an adhesive layer (S212) may be performed. The material of the adhesive layer and the adhesion force for each region of the adhesive layer have been described in detail with reference to FIGS. 7A and 7B and thus will not be repeated here. In the step of forming an adhesive layer (S212), a third protective layer PL3 may have a first adhesion force in an outer region SD.

Referring to FIGS. 9 and 10H, after the step of forming an adhesive layer (S212), the step of emitting UV light (S221) and irradiating a portion of an adhesive layer ADL may be performed. In the step of emitting UV light (S221), UV light may be emitted from a UV emission module (not illustrated) toward the adhesive layer ADL. Although not explicitly illustrated in the present specification, the step of emitting UV light (S221) may further include a step of selecting a region and a masking step.

In the step of selecting a region (not illustrated), a region to be exposed to UV light and a region not to be exposed to UV light may be selected in the adhesive layer ADL.

In the masking step (not illustrated), a masking member may be laminated over the region not to be exposed to UV light. The masking member may be, for example, a metal pattern.

In the step of emitting UV light (S221), a portion of the adhesive layer ADL that is exposed to (i.e., irradiated with) UV light may lose its adhesion force. The amount of UV irradiation in the step of emitting UV light (S221) is not limited to any particular amount. The light source for UV irradiation may be, for example, a high-pressure mercury lamp or a metal halide lamp.

In the step of emitting UV light (S221), the UV light may irradiate a region corresponding to at least a portion of a central region CT of the adhesive layer ADL. Accordingly, the region of the adhesive layer ADL that is exposed to UV light may have reduced adhesion. That is, the third protective layer PL3 may have a second adhesion force, which is smaller than the first adhesion force, in at least a portion of the central region.

Referring to FIGS. 9 and 10I, the step of attaching the third protective layer (S300) may be performed. In the step of attaching the third protective layer (S300), the third protective layer PL3 may be adhered to the base substrate BSB. Here, the third protective layer PL3 may be adhered to the base substrate BSB such that the outer region SD overlaps with a first dummy region DM1 and the central region CT overlaps with a target region TG. As described previously, since the outer region SD has not been irradiated with the UV light in the step of emitting UV light (S221), the third protective layer PL3 may have the first adhesion force in the outer region SD. Therefore, the third protective layer PL3 may be adhered to the base substrate BSB with the first adhesion force in the outer region SD and the first dummy region DM1. In some aspects, the third protective layer PL3 may have the second adhesion force in at least a portion of the central region CT. Preferably, the second adhesion force may be zero. However, the second adhesion force is not limited thereto and may be a predetermined adhesion force smaller than the first adhesion force.

Referring to FIGS. 9 and 10J, after the step of attaching the third protective layer (S300), the step of spraying an etchant (S400) may be performed. The etchant used in the step of spraying an etchant (S400) may include hydrofluoric acid (HF) or hydrofluoride-based substances. The step of spraying an etchant (S400) may be carried out using various methods, for example, a dipping method (not illustrated), a spraying method (not illustrated), or a top-down etching method (not illustrated).

In the dipping method, the base substrate BSB is vertically dipped into a bath to perform the etching. In the spraying method, the etchant is sprayed onto both sides of a vertically standing base substrate BSB through spray nozzles to etch the substrate. In the top-down etching method, the etchant is poured from the upper side to flow downward over the vertically standing base substrate BSB to perform the etching.

In the present specification, the top-down etching method will be described. The etchant may flow from the top of the base substrate BSB and infiltrate between pre-formed cell cut lines CTL on the opposite surface of the base substrate BSB. Accordingly, the thickness of the base substrate BSB may be reduced, and the base substrate BSB may be cut. For example, the thickness of the base substrate BSB may be reduced, but not limited to, from 500 μm to 200 μm. As the etchant infiltrates between the cell cut lines CTL, the plurality of cells CLL1 - CLL6 may eventually be cut and separated. The plurality of separated cells CLL1 - CLL6 may then be transported by a picker (not illustrated) for subsequent processing steps.

Referring to FIGS. 9 and 10K, after the step of spraying an etchant (S400), the step of peeling off the third protective layer (S500) may be performed. In the step of peeling off the third protective layer (S500), the third protective layer PL3 may be peeled off by a peeling pin (not illustrated). For example, the peeling pin (not illustrated) may grasp one side of the third protective layer PL3 and apply a force in a predetermined direction. As a result, the third protective layer PL3 may be detached from the base substrate BSB.

In an embodiment of the disclosure, the second protective layer PL2 may be detached from the base substrate BSB in the step of peeling off the third protective layer (S500). As previously described with reference to FIGS. 8B and 8C, this is because the second protective layer PL2 is disposed such that the second protective layer PL2 overlaps the first dummy region DM1 and the ends of the second protective layer PL2 are connected to each other. As the third protective layer PL3 is detached from the base substrate BSB, the second protective layer PL2, which is adhered to the third protective layer PL3, may also be readily peeled off.

In an embodiment of the disclosure, a cell cutting process is performed using an etchant when the display panel is fabricated. To prevent corrosion of the display panel by the etchant, the first protective layer PL1, second protective layer PL2, and third protective layer PL3 are sequentially adhered to the base substrate BSB. After the step of spraying the etchant, the techniques described herein include peeling off and removing the first protective layer PL1, second protective layer PL2, and third protective layer PL3 from the base substrate BSB. The present disclosure allows the third protective layer PL3 to have different adhesion forces in certain regions such that the third protective layer PL3 adheres only to the base substrate BSB and does not stick to the first and second protective layers PL1, PL2. Accordingly, when the third protective layer PL3 is peeled off from the base substrate BSB, the third protective layer PL3 can be smoothly detached without being adhered to the first and second protective layers PL1, PL2. Thus, the protective layers PL1, PL2, PL3 can be removed without damaging the plurality of cells CLL1 - CLL6.

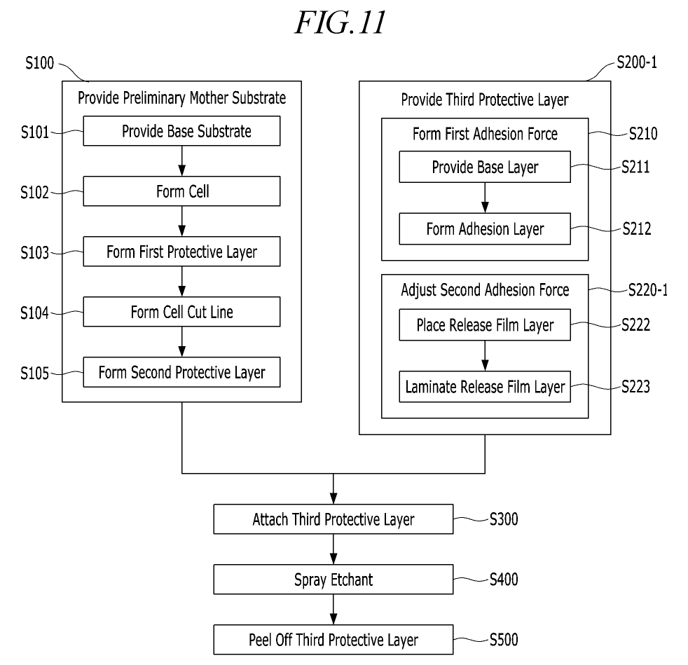

FIG. 11 is a flow diagram illustrating a display panel manufacturing method S10-1 according to another embodiment of the present disclosure. The display panel manufacturing method S10-1 may include providing a preliminary mother substrate (S100), providing a third protective layer (S200-1), attaching the third protective layer (S300), spraying an etchant (S400), and peeling off the third protective layer (S500).

The step of providing a preliminary mother substrate (S100) may include providing a base substrate (S101), forming a cell (S102), forming a first protective layer (S103), forming a cell cut line (S104), and forming a second protective layer (S105).

The step of providing a third protective layer (S200-1) may include forming a first adhesion force (S210) and adjusting a second adhesion force (S220-1). The step of forming a first adhesion force (S210) may include providing a base layer (S211) and forming an adhesive layer (S212). The step of adjusting a second adhesion force (S220-1) may include placing a release film layer (S222) and laminating the release film layer (S223).

Since the step of providing a preliminary mother substrate (S100) has been described in detail with reference to FIGS. 10A through 10E, repeated description will be omitted.

Likewise, the step of providing a base layer (S211) and the step of forming an adhesive layer (S212) are substantially the same as those described with reference to FIGS. 10F and 10G and will not be described redundantly.

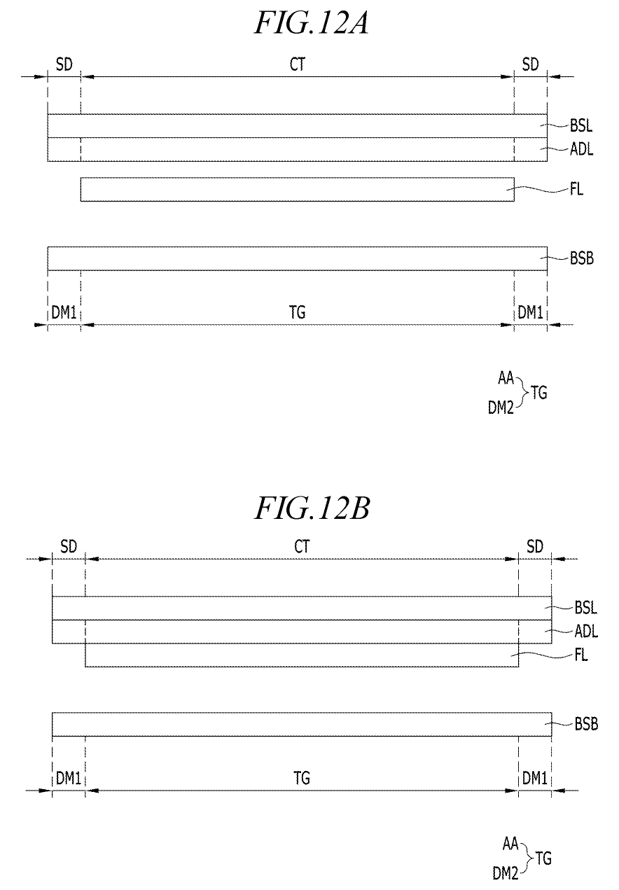

FIGS. 12A and 12B illustrate the step of adjusting a second adhesion force (S220-1) in the display panel manufacturing method S10-1.

Referring to FIGS. 11 and 12A, the step of placing a release film layer (S222) may be performed. In the step of placing a release film layer (S222), a release film layer FL may be placed below the adhesive layer ADL such that the release film layer FL overlaps with the target region TG and does not overlap with the first dummy region DM1.

Referring to FIGS. 11 and 12B, after the step of placing a release film layer (S222), the step of laminating the release film layer (S223) may be performed. In the step of laminating the release film layer (S223), pressure may be applied to the release film layer FL to laminate the release film layer FL with the adhesive layer ADL.

For example, the adhesive layer ADL and the release film layer FL may pass through a pressure roller (not illustrated) in a laminating machine (not illustrated) to ensure uniform lamination.

Although not explicitly illustrated, the laminated third protective layer PL3 may undergo an aging process for 2 to 4 days at a temperature of 40 to 60 °C. Through the aging process, any residual volatile components not yet evaporated from the third protective layer PL3 may be completely removed, resulting in a more uniform and dense bonding structure.

After undergoing the step of laminating the release film layer (S223), the third protective layer PL3 may have the release film layer FL overlapping a portion of the adhesive layer ADL, while the region of the adhesive layer ADL retaining adhesion force may not overlap with the release film layer FL. Accordingly, the third protective layer PL3 may have the first adhesion force in the first dummy region DM1.

The subsequent steps of attaching the third protective layer (S300), spraying an etchant (S400), and peeling off the third protective layer (S500) are substantially the same as those described previously with reference to FIGS. 10I, 10J, and 10K and thus will not be described repeatedly.

In an embodiment of the disclosure, after the step of peeling off the third protective layer (S500), a step of obtaining a cell (not illustrated) and a step of connecting a driving unit (not illustrated) may be further performed.

In the step of obtaining a cell (not illustrated), a plurality of cells CLL1 - CLL6 may be cut along the cell cut line CTL and obtained.

In the step of connecting a driving unit (not illustrated), the separated cells CLL1 - CLL6 may be connected to a driving unit. For example, the step of connecting a driving unit (not illustrated) may include mounting a driving IC, attaching a sensor layer or a window, and mounting signal pads PD of the display panel DP.

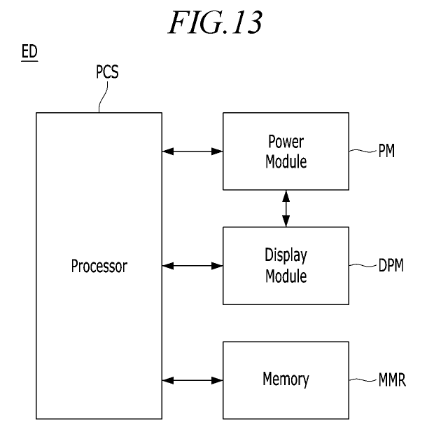

FIG. 13 is a block diagram illustrating an electronic device ED according to an embodiment of the disclosure. In the present specification, the electronic device ED according to an embodiment may include a display device and may further include other modules or devices having additional functions besides the display device.

Referring to FIG. 13, the electronic device ED according to an embodiment may include a display module DPM, a processor PCS, a memory MMR, and a power module PM.

The processor PCS may include at least one of a central processing unit (CPU), an application processor (AP), a graphic processing unit (GPU), a communication processor (CP), an image signal processor (ISP), and a controller.

The memory MMR may have data and information supportive of the operation of the processor PCS or the display module DPM stored therein. In an example in which the processor PCS executes an application stored in the memory MMR, an image data signal and/or an input control signal may be transferred to the display module DPM, which may then process the received signals and output image information through a display screen.

The power module PM may include a power supply module, such as, for example, a power adapter or a battery device, and a power conversion module configured to convert the power supplied from the power supply module into power for operating the electronic device ED.

At least one of the components of the electronic device ED described herein may be included in the display device according to the above-described embodiments. In some aspects, some of the individual modules functionally included in a single module may be included within the display device, while others may be provided separately from the display device. For example, the display device may include the display module DPM, and the processor PCS, memory MMR, and power module PM may be provided as separate components of the electronic device ED, rather than being part of the display device.

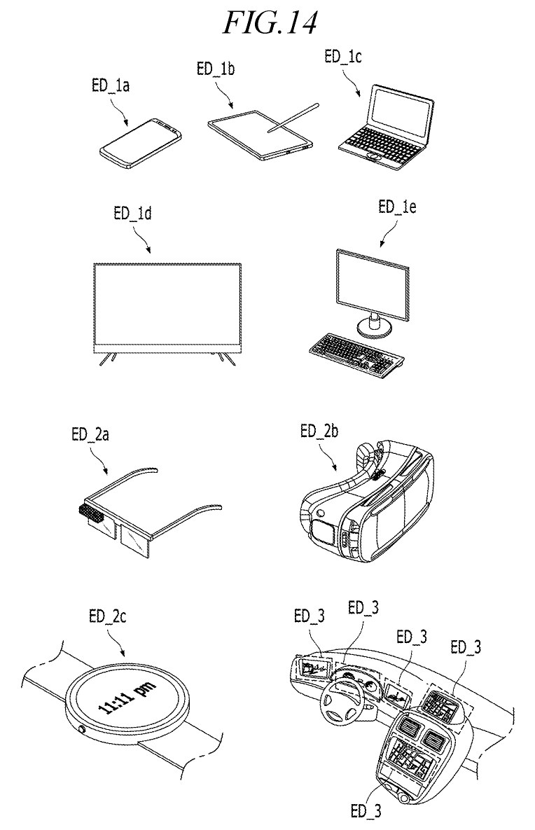

FIG. 14 illustrates schematic examples of electronic devices ED according to various embodiments. Referring to FIG. 14, the display device according to the embodiments of the present disclosure may be applied to various types of electronic devices ED, including not only image display electronic devices, such as, for example, a smartphone ED-1a, tablet PC ED-1b, laptop computer ED-1c, TV ED-1d, and desktop monitor ED-1e, but also wearable electronic devices, including a display module such as, for example, smart glasses ED-2a, head-mounted displays ED-2b, and smartwatches ED-2c. Moreover, the electronic device ED may include automotive electronic devices ED-3 having a display module, such as, for example, a center information display (CID) located in the instrument cluster, center fascia, or dashboard of a vehicle, or room mirror display.

Hitherto, certain example embodiments of the present disclosure have been described herein, but these are examples and are not intended to limit the present disclosure. Those skilled in the art to which the present disclosure pertains may make various modifications and changes to the embodiments by adding, changing, deleting, or adding certain elements, without departing from the scope of the technical ideas of the present disclosure as set forth in the claims, and such modifications and changes should also be regarded as being within the scope of the present disclosure.

What is claimed is:

1. A mother substrate comprising:
a base substrate defined with a target region and a first dummy region surrounding the target region, the target region comprising a plurality of active regions and a second dummy region surrounding the plurality of active regions;
a plurality of cells disposed on the base substrate and overlapping, respectively, with the plurality of active regions;
a first protective layer disposed on one of the plurality of cells and overlapping an active region of the plurality of active regions;
a second protective layer disposed on the base substrate and overlapping the second dummy region; and
a third protective layer disposed on the base substrate and defined with a central region and an outer region surrounding the central region,
wherein the third protective layer:
has a first adhesion force in the outer region and is adhered to the base substrate between the outer region and the first dummy region, and
has a second adhesion force smaller than the first adhesion force in at least a portion of the central region.

2. The mother substrate of claim 1, wherein the third protective layer comprises:
a base layer; and
an adhesive layer disposed below the base layer,
wherein:
the adhesive layer has the first adhesion force in the outer region, and
the adhesive layer has the second adhesion force in at least the portion of the central region.

3. The mother substrate of claim 1, wherein the third protective layer comprises:
a base layer;
an adhesive layer disposed below the base layer; and
a release film layer disposed below the adhesive layer,
wherein the release film layer overlaps the target region and is non-overlapping with the first dummy region.

4. The mother substrate of claim 2, wherein:
the adhesive layer has the second adhesion force in a portion of the central region overlapping the active region, and
the adhesive layer has the first adhesion force in a portion of the central region overlapping the second dummy region.

5. The mother substrate of claim 2, wherein the adhesive layer has the second adhesion force in the central region overlapping the active region and the second dummy region.

6. The mother substrate of claim 1, wherein:
an opening is defined in each of the plurality of cells,
a cell cut line overlapping the second dummy region is provided on an opposite surface of the base substrate, and
a thickness of the base substrate at the cell cut line is smaller than a thickness of the base substrate where the base substrate overlaps the active region.

7. The mother substrate of claim 6, wherein:
a subset of the plurality of cells arranged along a predetermined direction is defined as a cell row,
the second protective layer is disposed between the base substrate and the third protective layer, and
a portion of the second protective layer is disposed such that the portion overlaps with the first dummy region in a plan view.

8. The mother substrate of claim 7, wherein the second protective layer extends in the predetermined direction and shields the opening of each of the plurality of cells comprised in the cell row.

9. The mother substrate of claim 7, wherein:
the second protective layer is provided in plurality, and
the plurality of second protective layers comprise:
a first sub-protective layer surrounding an edge of a first cell among the plurality of cells comprised in the cell row; and
a second sub-protective layer surrounding an edge of a second cell adjacent to the first cell in the predetermined direction among the plurality of cells comprised in the cell row.

10. The mother substrate of claim 9, wherein the plurality of second protective layers further comprise:
an auxiliary line connecting the first sub-protective layer with the second sub-protective layer; and
a dummy line overlapping the first dummy region.

11. A method of manufacturing a display panel, the method comprising:
providing a preliminary mother substrate comprising:
a base substrate defined with a target region and a first dummy region surrounding the target region, wherein the target region comprises a plurality of active regions and a second dummy region surrounding the plurality of active regions,
a plurality of cells disposed on the base substrate,
a first protective layer, and
a second protective layer;
providing a third protective layer having:
a first adhesion force in an outer region of the third protective layer, and
a second adhesion force smaller than the first adhesion force in at least a portion of a central region of the third protective layer surrounded by the outer region; and
attaching the third protective layer to the base substrate such that the outer region overlaps the first dummy region and the central region overlaps the target region.

12. The method of claim 11, wherein the providing of the third protective layer comprises:
forming the first adhesion force such that the third protective layer has the first adhesion force in the outer region; and
adjusting the second adhesion force such that the second adhesion force is smaller than the first adhesion force in at least the portion of the central region.

13. The method of claim 12, wherein:
the forming of the first adhesion force comprises:
providing a base layer; and
forming an adhesive layer having the first adhesion force below the base layer, and
the adjusting of the second adhesion force comprises irradiating a portion of the adhesive layer corresponding to at least the portion of the central region with ultraviolet (UV) light.

14. The method of claim 12, wherein:
the forming of the first adhesion force comprises:
providing a base layer; and
forming an adhesive layer having the first adhesion force below the base layer, and
the adjusting of the second adhesion force comprises:
placing a release film layer below the adhesive layer such that the release film layer overlaps the target region and does not overlap the first dummy region; and
laminating the release film layer with the adhesive layer by applying pressure to the release film layer.

15. The method of claim 11, wherein the providing of the preliminary mother substrate comprises:
providing the base substrate;
forming the plurality of cells on the base substrate, wherein the plurality of cells respectively overlap the plurality of active regions, and an opening is defined in each of the plurality of cells;
forming a first protective layer by coating the plurality of cells with a first organic material;
forming a cell cut line between the plurality of cells by irradiating an opposite surface of the base substrate with a laser; and
forming a second protective layer which overlaps with the cell cut line by coating the base substrate with a second organic material.

16. The method of claim 15, further comprising spraying an etchant from above the base substrate, after the attaching of the third protective layer to the base substrate,
wherein, in the spraying of the etchant, the plurality of cells are cut along the cell cut line.

17. The method of claim 16, further comprising peeling off the third protective layer from the base substrate, after the spraying of the etchant.

18. The method of claim 17, wherein in the forming of the second protective layer, the second protective layer is disposed between the base substrate and the third protective layer, and, in a plan view, a portion of the second protective layer overlaps with the first dummy region.

19. The method of claim 18, wherein in the peeling off the third protective layer, the second protective layer is detached from the base substrate.

20. A method of manufacturing an electronic device, the method comprising:
providing a preliminary mother substrate comprising:
a base substrate defined with a target region and a first dummy region surrounding the target region, wherein the target region comprises a plurality of active regions and a second dummy region surrounding the plurality of active regions,
a plurality of cells disposed on the base substrate,
a first protective layer, and
a second protective layer overlapping with a cell cut line of the base substrate;
providing a third protective layer having:
a first adhesion force in an outer region of the third protective layer, and
a second adhesion force smaller than the first adhesion force in at least a portion of a central region of the third protective layer surrounded by the outer region;
attaching the third protective layer to the base substrate such that the outer region overlaps the first dummy region and the central region overlaps the target region;
spraying an etchant from above the base substrate, wherein spraying the etchant cuts and separates the plurality of cells along the cell cut line; and
connecting the separated plurality of cells with a driving unit.
